(19) United States
(12) Patent Application Publication
(10) Pub. No.: US 2026/0308449 A1
(43) Pub. Date: Oct. 8, 2026

(54) Composition For TiN Hard Mask Removal While Compatible With Tungsten

(71) Applicant: Versum Materials US, LLC, TEMPE, AZ (US)

(72) Inventors: Yuanmei Cao, Chandler, AZ (US); Laisheng Sun, Gilbert, AZ (US); Aaron Pejlovas, Tempe, AZ (US); Jhih-Kuei Ge, New Taipei City (TW); Aiping Wu, Chandler, AZ (US)

(21) Appl. No.: 19/483,103

(22) PCT Filed: May 6, 2024
(86) PCT No.: PCT/US2024/027941

§ 371 Date: Nov. 10, 2025

Related U.S. Application Data
(60) Provisional application No. 63/501,404, filed on May 11, 2023.

(51) Int. Cl. C09K 13/06

(52) U.S. Cl. CPC C09K 13/06

(57) ABSTRACT

Composition, method and system for TiN hard mask removal from electronic circuitry devices, such as advanced pattern wafers, have been disclosed. The etching formulations include, consist essentially of or consist of (a) at least one phosphorous containing acid or salt thereof, (b) at least one oxidizing agent, (c) at least one at least one cationic polymer corrosion inhibitor and (d) at least one solvent.

### BACKGROUND

### Field

The disclosed and claimed subject matter relates to formulations that selectively etch TiN layer over tungsten (W) as well as methods of manufacturing the same and/or employing the same for fabricating a semiconductor device.

### Related Art

As scaling continues to ever smaller feature sizes, integrated circuit (IC) reliability is an increasing concern in IC fabrication technology. The impact of trace interconnect failure mechanisms on device performance and reliability demand much more from integration schemes, interconnect materials, and processes. Titanium nitride (TiN) has been used as hard mask layer that is deposited other material layers for different applications. For example, an optimal low-k dielectric material and its related deposition, pattern lithography, etching and cleaning are required to form dual-damascene interconnect patterns. The dual-damascene process involves forming a photoresist mask, typically a titanium, or titanium nitride (TiN) on a low-k dielectric layer overlying a metal conductor layer, such as a copper or a cobalt layer. The low-k dielectric layer is then etched in those regions not protected by the photoresist mask to form a via and/or trench that expose the metal conductor layer. The via and trench, commonly known as dual-damascene structure, are usually defined using two lithography steps. The photoresist mask is then removed from the low-k dielectric layer before a conductive material is deposited into the via and/or trench to form an interconnect. A hard-mask scheme approach of interconnects-patterning wafer fabrication allows the transfer of patterns into the under layers with tightest optimal dimension control.

In other applications, TiN layer may be directly deposited on layers of different metal materials without dielectric layers in between for dimension control. Those metal material may include aluminum, copper, cobalt, molybdenum, tungsten etc.

Compositions have been developed to partially etch or completely remove these types of metal hard masks from substrates without damaging the exposed materials.

To protect those exposed metal layers, inhibitors are usually added into the compositions to prevent the metal layer loss to obtain better metal surface for later metal deposition. Different from the compositions for selectively removing TiN hard mask over exposed copper or cobalt, for which there are many good inhibitors available to protect their surface, there are few compositions that could selectively remove TiN layer over tungsten due to the limited inhibitors for protecting W. Therefore, there is a need to develop compositions that could etch significant amount titanium nitride mask layer while protect the exposed tungsten layer from etching.

### SUMMARY

The disclosed and claimed subject matter relates to formulations that selectively etch TiN layer over tungsten (W) as well as methods of manufacturing the same and/or employing the same for fabricating a semiconductor device.

In one embodiment, the etching formulations include, consist essentially of or consist of:
(a) at least one phosphorous containing acid or salt thereof;
(b) at least one oxidizing agent;
(c) at least one cationic polymer corrosion inhibitor; and
(d) at least one solvent.

The disclosed and claimed subject matter further includes a method of using the disclosed and claimed etching compositions to selectively remove a TiN layer while minimizing the etch rate of W layer and to a method for fabricating a semiconductor, which includes an etching process employing the disclosed and claimed etching compositions.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter.

Preferred embodiments of this disclosed and claimed subject matter are described herein, including the best mode known to the inventors for carrying out the disclosed and claimed subject matter. Variations of those preferred embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, this disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

For ease of reference, “microelectronic device” or “semiconductor substrates” correspond to semiconductor wafers, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly. The microelectronic device or semiconductor substrates may include low-k dielectric material, barrier materials, and metals, such as, AlCu alloys, W, Ti, TiN, as well as other materials thereon.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 2 wt. %, preferably less than 1 wt. %, more preferably less than 0.5 wt. %, and most preferably less than 0.1 wt. %. “Substantially free” also includes 0.0 wt. %. The term “free of” means 0.0 wt. %.

As used herein, the terms “about” and “approximately” are each intended to correspond to ±5% of the stated value.

As used herein, “neat” refers to the weight % amount of an undiluted acid or other material. For example, the inclusion 100 g of 85% phosphoric acid constitutes 85 g of the acid and 15 grams of diluent.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all defined weight percents of the components unless otherwise indicated are based on the total weight of the composition. Further, all weight percents unless otherwise indicated are “neat” meaning that they do not include the aqueous composition in which they are present when added to the composition. Any reference to “at least one” could be substituted with “one or more.” “At least one” and/or “one or more” includes “at least two” or “two or more” and “at least three” and “three or more” and so on.

In the broad practice the disclosed and claimed subject matter pertains to the above-described etching composition which includes, or consists essentially of, or consists of components (a), (b), (c), and (d). In some aspect, the etching compositions can include other ingredients. In some embodiments, the etching compositions disclosed herein are formulated to be free or substantially free of at least one of the following chemical compounds: inorganic bases, quaternary ammonium hydroxides, ammonium hydroxide, amino acids, organic acids, azoles, halide ions (e.g., fluoride ions, chloride ions), metal-containing chemicals, reducing agents, alkanolamine, hydroxylamine, hydroxylamine derivatives, amidoxime compounds, organic solvents, surfactants and abrasives.

In a further embodiment, the etching compositions consist essentially of a), (b), (c), and (d) in varying concentrations. In such an embodiment, the combined amounts of a), (b), (c), and (d) do not equal 100% by weight and can include other ingredients that do not materially change the effectiveness of the etching compositions.

In another embodiment, the etching compositions consist of a), (b), (c), and (d) in varying concentrations. In such an embodiment, the combined amounts of a), (b), (c), and (d) equal or equal approximately 100% by weight but may include other small and/or trace amounts of impurities that are present in such small quantities that they do not materially change the effectiveness of the composition. For example, in one such embodiment, the etching composition can contain 2% by weight or less of impurities. In another embodiment, the etching composition can contain 1% by weight or less than of impurities. In a further embodiment, the etching composition can contain 0.05% by weight or less than of impurities.

When referring to compositions of the inventive composition described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the etching composition can contain 2% by weight or less of impurities. In another embodiment, the etching composition can contain 1% by weight or less than of impurities. In a further embodiment, the etching composition can contain 0.05% by weight or less than of impurities. In other such embodiments, the ingredients can form at least 90 wt %, more preferably at least 95 wt %, more preferably at least 99 wt %, more preferably at least 99.5 wt %, most preferably at least 99.9 wt %, and can include other ingredients that do not materially affect the performance of the etching compositions. Otherwise, if no significant non-essential impurity component is present, it is understood that the combination of all essential constituent components will essentially add up to 100 weight %.

The ensuing detailed description provides preferred exemplary embodiments only, and is not intended to limit the scope, applicability, or configuration of the disclosed and claimed subject matter. Rather, the ensuing detailed description of the preferred exemplary embodiments will provide those skilled in the art with an enabling description for implementing the preferred exemplary embodiments of the disclosed and claimed subject matter. Various changes may be made in the function and arrangement of elements without departing from the spirit and scope of the disclosed and claimed subject matter, as set forth in the appended claims.

### Etching Formulations

Disclosed herein are etching formulations of chemical strippers for TiN hard mask or TiN thin layer removal or etching (“removal” and “etching” are used interchangeably herein) on integrated circuit bearing wafers. TiN hard mask or TiN thin layer is used to provide fine feature control during plasma etching. Suitable stripper/cleaning chemistries must be able to pull back or totally remove the TiN hard mask or TiN thin layer as well as any residues from the plasma etch process. However, it is also desirable for such chemistries to provide compatibility with tungsten within the device.

In particular, the disclosed and claimed etching formulations include, consist essentially of or consist of:
(a) at least one phosphorous containing acid or salt thereof;
(b) at least one oxidizing agent;
(c) at least one cationic polymer corrosion inhibitor; and
(d) at least one solvent.

In some aspects of this embodiment, the etching formulations can include other optional ingredients.

### (a) Phosphorous Containing Acid or Salt Thereof

The disclosed and claimed etching formulations include at least one phosphorous containing acid or salt thereof as an etchant agent. Phosphorous containing acids, and their salts may include but are not limited to phosphoric acid, tetramethylammonium phosphate, tetrabutylammonium phosphate, tetraethylammonium phosphate, tetrapropylammoniumphosphate, etidronic acid, amino trimethylene phosphonic acid, tripolyphosphoric acid, tetrapolyphosphoric acid, pyrophosphoric acid, polymetaphosphoric acid, hypophosphorous acid, phosphorous acid, diphosphorous acid, triphosphorous acid, (aminomethyl)phosphonic acid, (aminoethyl)phosphonic acid, (aminopropyl)phosphonic acid, mono-n-dodecyl phosphate, tetramethylammonium phosphate, tetrabutylammonium phosphate, tetraethylammonium phosphate, tetrapropylammoniumphosphate and combinations thereof. In one embodiment, at least one phosphorous containing acid or salt thereof includes phosphoric acid.

The amount of the at least one phosphorous containing acid or salt thereof in the formulations of the disclosed and claimed subject matter is in a percent weight (neat), based on the total weight of the formulations, within any range having start and end points selected from the following: 5, 10, 15, 20, 25, 30, 35, 40, 45, 50, 55, 60, 65, 70, 75, 80, 85, 90, 95. These include, but are not limited to: from about 5-95%, 10-90%, 20-90%, 30 wt % to about 90 wt % of the formulation; from about 9 wt % to about 70 wt % of the formulation; from about 9 wt % to about 60 wt % of the formulation; from about 25 wt % to about 50 wt % of the formulation; from about 40 wt % to about 90 wt % of the formulation; from about 50 wt % to about 90 wt % of the formulation; from about 60 wt % to about 90 wt % of the formulation; from about 30 wt % to about 80 wt % of the formulation; from about 40 wt % to about 80 wt % of the formulation; from about 45 wt % to about 80 wt % of the formulation; from about 50 wt % to about 80 wt % of the formulation; from about 60 wt % to about 80 wt % of the formulation; from about 9 wt % to about 75 wt % of the formulation, from about 30 wt % to about 75 wt % of the formulation; from about 40 wt % to about 75 wt % of the formulation; from about 45 wt % to about 75 wt % of the formulation; from about 50 wt % to about 75 wt % of the formulation. In one embodiment, at least one phosphorous containing acid or salt thereof is present from about 30 wt % to about 75 wt % of the formulation. In one embodiment, at least one phosphorous containing acid or salt thereof is present from about 40 wt % to about 75 wt % of the formulation. In one embodiment, at least one phosphorous containing acid or salt thereof is present from about 45 wt % to about 75 wt % of the formulation. In one embodiment, at least one phosphorous containing acid or salt thereof is present from about 30 wt % to about 55 wt % of the formulation. In one embodiment, at least one phosphorous containing acid or salt thereof is present from about 25 wt % to about 50 wt % of the formulation. In one embodiment, at least one phosphorous containing acid or salt thereof is present from about 25 wt % to about 45 wt % of the formulation. In one embodiment, at least one phosphorous containing acid or salt thereof is present from about 30 wt % to about 50 wt % of the formulation. These percentages and ranges represent the neat amount of the at least one phosphorous containing acid or salt thereof in the formulations.

### (b) Oxidizing Agent

The disclosed and claimed etching formulations include at least one oxidizing agent. The cleaning compositions employ a peroxide such as, for example, hydrogen peroxide, as an oxidizing agent for TiN hard mask removal. The peroxide to be used in the composition may include but is not limited to hydrogen peroxide, ammonium persulfate, peracetic acid, peroxybenzoic acid, oxone (2KHSO₅·KHSO₄·K₂SO₄), n-methylmorpholine oxide (NMMO or NMO), benzoyl peroxide, tetrabutylammonium peroxymonosulfate, ferric chloride, permanganate peroxoborate, periodic acid, iodic acid, vanadium (V) oxide, vanadium (IV, V) oxide, ammonium vanadate, perchlorate, persulfate, ammonium peroxydisulfate, per acetic acid, urea hydroperoxide, nitric acid (HNO₃), ammonium hypochlorite (NH₄CIO), ammonium tungstate ((NH₄)₁₀H₂(W₂O₇)), ammonium chlorite (NH₄CIO₂), ammonium chlorate (NH₄CIO₃), ammonium iodate (NH₄IO₃), ammonium perborate (NH₄BO₃), ammonium perchlorate (NH₄CIO₄), ammonium periodate (NH₄IO₃), ammonium persulfate ((NH₄)₂S₂O₈), tetramethylammonium chlorite ((N(CH₃)₄) CIO₂), tetramethylammionium chlorate ((N(CH₃)₄) CIO₃), tetramethylammonium iodate ((N(CH₃)₄) IO₃), tetramethylammonium perborate ((N(CH₃)₄) BO₃), tetramethylammonium perchlorate ((N(CH₃)₄) CIO₄), tetramethylammonium periodate ((N(CH₃)₄) IO₄), tetramethylammonium persulfate ((N(CH₃)₄)S₂O₈), ((CO(NH₂)₂)H₂O₂), peracetic acid (CH(CO)OOH) and combinations thereof. In one embodiment, the oxidizing agent includes hydrogen peroxide.

The amount of the at least one oxidizing agent in the formulations of the disclosed and claimed subject matter is in a percent weight (neat), based on the total weight of the formulations, within any range having start and end points selected from the following: 1, 2, 3, 4, 5, 6, 7, 8, 9, 10, 11, 12, 13, 14, 15, 16, 17, 18, 19, 20, 21, 22, 24, 26, 28, 30, 35, 40, 45, 50, 55, 60, 65, 70. For example, from about 1 wt % to about 20 wt % of the formulations, or from about 1 wt % to about 15 wt % or from about 1 wt % to about 10 wt %, from about 1 wt % to about 6 wt %, or from about 3 wt % to about 20 wt %, or from about 3 wt % to about 15 wt %, from about 3 wt % to about 6 wt %, or from about 6 wt % to about 20 wt %, or from about 6 wt % to about 15 wt %, preferably from about 3 wt % to about 15 wt % and more preferably from about 6 wt % to about 15 wt %.

In one embodiment, the at least one oxidizing agent includes hydrogen peroxide in an amount in the formulations of from about 15 wt % to about 70 wt %. In one embodiment, the at least one oxidizing agent includes hydrogen peroxide in an amount in the formulations of from about 15 wt % to about 65 wt %. In one embodiment, the at least one oxidizing agent includes hydrogen peroxide in an amount in the formulations of from about 15 wt % to about 50 wt %. In one embodiment, the at least one oxidizing agent includes hydrogen peroxide in an amount in the formulations of from about 15 wt % to about 40 wt %. In one embodiment, the at least one oxidizing agent includes hydrogen peroxide in an amount in the formulations of from about 15 wt % to about 30 wt %. In one embodiment, the at least one oxidizing agent includes hydrogen peroxide in an amount in the formulations of from about 20 wt % to about 65 wt %. In one embodiment, the at least one oxidizing agent includes hydrogen peroxide in an amount in the formulations of from about 45 wt % to about 65 wt %. In one embodiment, the at least one oxidizing agent includes hydrogen peroxide in an amount in the formulations of from about 20 wt % to about 45 wt %. In one embodiment, the oxidizing agent hydrogen peroxide in an amount in the formulations of about 13.5 wt %. In one embodiment, the oxidizing agent hydrogen peroxide in an amount in the formulations of about 19.5 wt %. In one embodiment, the oxidizing agent hydrogen peroxide in an amount in the formulations of about 6 wt %. In one embodiment, the at least one oxidizing agent includes hydrogen peroxide in an amount in the formulations of about 45 wt %. In one embodiment, the at least one oxidizing agent includes hydrogen peroxide in an amount in the formulations of about 65 wt %. These percentages and ranges represent the neat amount of the at least one oxidizing agent in the formulations.

### (c) Corrosion Inhibitor

The disclosed and claimed etching formulations include at least one cationic polymer corrosion inhibitor. The at least one cationic polymer corrosion inhibitor helps minimize loss of metal substrates such as tungsten. The cationic polymer corrosion inhibitors to be used in the formulations include, but are not limited to, polyalkyleneimine and its derivatives, poly(diallyldimethylammonium chloride), diallyldimethylammonium chloride and combinations thereof.

The polyalkyleneimines may be linear or branched and charged or uncharged. They may contain primary, secondary, and/or tertiary amino groups. They may be substituted, for example, by reaction with fatty acids, carboxylic acid and/or carboxylic acid derivatives (such as acrylic acid, maleic acid, maleic anhydride, etc.), alkylene oxides, etc. They may be alkoxylated, amidated, etc. They may be amphiphilic, amphoteric, alkoxylated, etc. In some embodiments, they may have molecular weights of from about 300 to about 2,000,000. Preferred polyalkyleneimines include polyethyleneimine.

Linear polyethylenimine (PEI) is a polymer with repeating units composed of an amine group and a two-carbon aliphatic-CH₂CH₂-spacer:

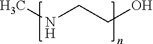

Linear polyethyleneimines contain all secondary amines, in contrast to branched PEIs which contain primary, secondary and tertiary amino groups. It should be noted that linear and branched polyethyleneimines and their mixtures are useful in the disclosed and claimed formulations to prevent tungsten etch.

Polyethyleneimines can have an average molecular weight (weight averaged, Mw) of about 100 to about 5,000,000 or even higher. Any polyethyleneimine is suitable for use in the disclosed and claimed etching formulations. It is preferred, however, that if one or more polyethyleneimine is used in the disclosed and claimed etching formulations that it have a typical average molecular weight (weight averaged, Mw) of up to about 1,000,000, preferably from about 200 to about 100,000, more preferably from about 300 to about 10,000 and more preferably from about 300 to about 5,000.

Polyethyleneimine examples include materials sold by BASF under the trade name Lupasol® and by Nippon Shokubai under the trade name EPOMIN®. Examples include Lupasol® FG, Lupasol® G 20, Lupasol® G 35, Lupasol® G 100, Lupasol® G 500, Lupasol® HF, Lupasol® P, Lupasol® PS, Lupasol® PR 8515, Lupasol® WF, Lupasol® FC, Lupasol® PE, Lupasol® HEO 1, Lupasol® PN 50, Lupasol® PN 60, Lupasol® PO 100, Lupasol® SK, etc. The preferred Lupasol® FG is a branched polyethylenimine polymer with a molecular weight of 800 g/mol.

Polydiallyldimethylammonium chloride is a homopolymer of diallyldimethylammonium chloride. The molecular weight of polyDADMAC is typically in the range of hundreds of thousands of grams per mole, and even up to a million for some products. The preferred polydiallyldimethylammonium chloride has a typical average molecular weight (weight averaged, Mw) of up to about 1,000,000, preferably from about 200 to about 100,000, more preferably from about 300 to about 10,000, more preferably from about 300 to about 5,000.

The amount of the at least one cationic polymer corrosion inhibitor in the formulations of the disclosed and claimed subject matter is in a percent weight (neat), based on the total weight of the formulations, within any range having start and end points selected from the following: 0.001, 0.005, 0.1, 0.2, 0.3, 0.5, 1, 2, 3, 4, 5, 6, 7, 8, 9, 10, 11, 12, 13, 14, 15, 16, 17, 18, 19, 20, 21, 22, 24, 26, 28. In one embodiment, the cationic polymer is present in an amount of from about 0.001 wt % to about 5 wt %. In one embodiment, the cationic polymer is present in an amount of from about 0.001 wt % to about 3 wt %. In one embodiment, the cationic polymer is present in an amount of from about 0.001 wt % to about 2 wt %. In one embodiment, the cationic polymer is present in an amount of from about 0.001 wt % to about 1 wt %. In one embodiment, the cationic polymer is present in an amount of from about 0.001 wt % to about 0.5 wt %. In one embodiment, the cationic polymer is present in an amount of from about 0.001 wt % to about 0.25 wt %. In one embodiment, the cationic polymer is present in an amount of from about 0.001 wt % to about 0.1 wt %. In one embodiment, the cationic polymer is present in an amount of from about 0.005 wt % to about 5 wt %. In one embodiment, the cationic polymer is present in an amount of from about 0.005 wt % to about 3 wt %. In one embodiment, the cationic polymer is present in an amount of from about 0.005 wt % to about 1 wt %. In one embodiment, the cationic polymer is present in an amount of from about 0.01 wt % to about 5 wt %. In one embodiment, the cationic polymer is present in an amount of from about 0.01 wt % to about 3 wt %. In one embodiment, the cationic polymer is present in an amount of from about 0.01 wt % to about 1 wt %. In one embodiment, the cationic polymer is present in an amount of from about 0.01 wt % to about 0.5 wt %. In one embodiment, the cationic polymer is present in an amount of from about 0.03 wt % to about 0.05 wt %. In one embodiment, the cationic polymer is present in an amount of from about 0.03 wt % to about 1.5 wt %. In one embodiment, the cationic polymer is present in an amount of from about 0.05 wt % to about 1.5 wt %. In one embodiment, the cationic polymer is present in an amount of about 0.01 wt %. In one embodiment, the cationic polymer is present in an amount of about 0.05 wt %. In one embodiment, the cationic polymer is present in an amount of about 0.15 wt %. In one embodiment, the cationic polymer is present in an amount of about 0.5 wt %. In one embodiment, the cationic polymer is present in an amount of about 1.0 wt %. In one embodiment, the cationic polymer is present in an amount of about 1.5 wt %. These percentages and ranges represent the neat amount of the at least one cationic polymer corrosion inhibitor in the formulations.

### (d) Solvent

As noted above, the disclosed and claimed etching formulations include at least one solvent.

In one embodiment, the at least one solvent includes, consists essentially of or consists of water. The water may be deionized water (“DI water”), purified water and/or distilled water.

In another embodiment, the at least one solvent includes water and one or more non-aqueous solvent. Examples of non-aqueous solvents that may be used in the formulations include, but are not limited to, dimethyl sufoxide (DMSO), dimethyl sulfone (DMSO₂), sulfolane ((CH₂)₄SO₂), n-methylpyrrolidone, glycol ether (e.g., dipropyleneglycolmethylether, tripropyleneglycolmethyl ether), glycols (e.g., propylene glycol) and combinations thereof. In one embodiment, the at least one solvent includes DMSO.

In one embodiment, the at least one solvent is present in an amount of from about 30 wt % to about 80 wt % of the composition. In one embodiment, the at least one solvent is present in an amount of from about 5 wt % to about 60 wt % of the composition. In one embodiment, the at least one solvent is present in an amount of from about 5 wt % to about 50 wt % of the composition. In one embodiment, the at least one solvent is present in an amount of from about 10 wt % to about 50 wt % of the composition. In one embodiment, the at least one solvent is present in an amount of from about 20 wt % to about 50 wt % of the composition. In one embodiment, the at least one solvent is present in an amount of from about 30 wt % to about 50 wt % of the composition. In one embodiment, the at least one solvent is present in an amount of from about 40 wt % to about 50 wt % of the composition. In one embodiment, the at least one solvent is present in an amount of from about 5 wt % to about 40 wt % of the composition. In one embodiment, the at least one solvent is present in an amount of from about 5 wt % to about 45 wt % of the composition. In one embodiment, the at least one solvent is present in an amount of from about 5 wt % to about 30 wt % of the composition. In one embodiment, the at least one solvent is present in an amount of from about 5 wt % to about 25 wt % of the composition. In one embodiment, the at least one solvent is present in an amount of from about 5 wt % to about 20 wt % of the composition. In one embodiment, the at least one solvent is present in an amount of from about 5 wt % to about 10 wt % of the composition. In one embodiment, the at least one solvent is present in an amount of from about 5 wt % to about 30 wt % of the composition. In one embodiment, the at least one solvent is present in an amount of from about 10 wt % to about 30 wt % of the composition. In one embodiment, the at least one solvent is present in an amount of from about 1 wt % to about 7 wt % of the composition. In one embodiment, the at least one solvent is present in an amount of from about 1 wt % to about 5 wt % of the composition.

### Optional Ingredients

The disclosed and claimed compositions may contain one or more optional ingredients. Such optional ingredients include, but are not limited to, the following:

### Chelating Agents

The disclosed and claimed etching formulations may optionally include one or more chelating agent, such as a metal chelating agent. Examples of suitable chelating agents include, but are not limited to, glycine, citric acid, serine, proline, leucine, alanine, asparagine, aspartic acid, glutamine, valine, and lysine, nitrilotriacetic acid, iminodiacetic acid, ethylenediaminetetraacetic acid (EDTA), (1,2-cyclohexylenedinitrilo)tetraacetic acid (CDTA), uric acid, tetraglyme, diethylenetriamine pentaacetic acid, propylenediamine tetraacetic acid, ethylendiamine disuccinic acid, sulfanilamide, 1,4,7,10-tetraazacyclododecane-1,4,7,10 tetraacetic acid; ethylene glycol tetraacetic acid (EGTA); 1.2-bis(o-aminophenoxy) ethane-N,N,N′,N′-tetraacetic acid; N-2-bis(carboxymethyl)aminoethyl-N-(2-hydroxy ethyl)glycine (HEDTA); and ethylenediamine-N,N′-bis(2-hydroxyphenylacetic acid) (EDDHA), 1,3-Diaminopropane-N,N,N′,N′-tetraacetic acid, gluconic acid, N,N,N′,N′-ethylenediaminetetrakis(methylenephosphonic acid), ntrilotris(methylene)triphosphonic acid, tartaric acid, 3,4-dihydroxybenzoic acid, salicylic acid, 8-HQ, N-(2-hydroxyethyl)ethylenediamine-N,N′,N′-triacetic acid, 1,3-Propanediamine-N,N,N′,N′-tetraacetic acid, glutamic acid, cystine, picolinic acid and combinations thereof. In one embodiment, the disclosed and claimed etching formulations include one or more of glycine, citric acid, ethylenediaminetetraacetic acid (EDTA) and picolinic acid.

The amount of the chelating agent, if present, in the formulations of the disclosed and claimed subject matter is in a percent weight (neat), based on the total weight of the formulations, within a range of about 0.0001 wt % to about 10 wt %, more preferably about 0.0001 wt % to about 5 wt % and most preferably from about 0.01 wt % to about 2 wt %.

### Ammonium Salt

The disclosed and claimed etching formulations may optionally include one or more ammonium salt. Examples of suitable ammonium salts include, but are not limited to, ammonium salts of weak acids and include triammonium citrate, ammonium acetate, ammonium malonate, ammonium adipate, ammonium lactate, ammonium iminodiacetate, ammonium chloride, ammonium bromide, ammonium fluoride, ammonium bifluoride, ammonium sulfate, ammonium oxalate, ammonium lactate, ammonium tartrate, ammonium citrate tribasic, ammonium acetate, ammonium carbamate, ammonium carbonate, ammonium benzoate, tetraammonium EDTA, ethylenediaminetetraacetic acid diammonium salt, ammonium succinate, ammonium formate, ammonium 1-H-pyrazole-3-carboxylate and combinations thereof. In one embodiment, the disclosed and claimed etching formulations include one or more of triammonium citrate and ammonium acetate.

The amount of the ammonium salt, if present, in the formulations of the disclosed and claimed subject matter is in a percent weight (neat), based on the total weight of the formulations, within a range of from about 0.1 wt % to about 20 wt %, more preferably from about 0.5 wt % to about 10 wt % and most preferably from about 0.5 wt % to about 5 wt % of the pre-diluted composition.

### Excluded Ingredients

In some embodiments, the etching compositions disclosed herein are formulated to be free or substantially free of at least one of the following chemical compounds: inorganic bases, quaternary ammonium hydroxides, ammonium hydroxide, alkanolamine, amino acids, organic acids, azoles, halide ions (e.g., fluoride ions, chloride ions), metal-containing chemicals, reducing agents, hydroxylamine, hydroxylamine derivatives, amidoxime compounds, organic solvents (e.g., DMSO), surfactants and abrasives.

In some embodiments, the formulations may be substantially free of or free of a halide-containing compound, for example it may be substantially free or free of one or more of the following: fluorine, bromine-, chlorine- or iodine-containing compounds. In other embodiments, the formulations may be substantially free or free of sulfates and/or nitrates and/or sulfites and/or nitrites.

In some embodiments, the disclosed and claimed etching formulations are substantially free of or free of: ammonium hydroxide and/or ethyl diamine. In other embodiments, the solution may be substantially free of or free of: sodium-containing compounds and/or calcium-containing compounds and/or manganese-containing compounds or magnesium-containing compounds and/or chromium-containing compounds and/or sulfur-containing compounds. In other embodiments, the solution may be substantially free or free of amidoxime compounds and/or abrasives.

In some embodiments, the disclosed and claimed etching formulations are substantially free of or free of other ammonium salts and/or quaternary ammonium hydroxide and metal ions.

In some embodiments, the disclosed and claimed etching formulations are substantially free of or free of alkanolamine.

pH

The disclosed and claimed etching formulations preferably have a pH of less than about 7. In one embodiment, the disclosed and claimed etching formulations have a pH of less than 6. In one embodiment, the disclosed and claimed etching formulations have a pH of less than 5. In one embodiment, the disclosed and claimed etching formulations have a pH of less than 4. In one embodiment, the disclosed and claimed etching formulations have a pH of less than 3. In one embodiment, the disclosed and claimed etching formulations have a pH of less than 2. In one embodiment, the disclosed and claimed etching formulations have a pH of less than 1. In one embodiment, the disclosed and claimed etching formulations have a pH of less than 0.5. In another embodiment, the disclosed and claimed etching formulations have a pH of between about 0.1 and about 3. In another embodiment, the disclosed and claimed etching formulations have a pH of between about 0.1 and about 1. Preferably, the pH is between about 0.1 and about 0.5.

In one embodiment, the disclosed and claimed etching formulations have a pH of about 5. In one embodiment, the disclosed and claimed etching formulations have a pH of about 5. In one embodiment, the disclosed and claimed etching formulations have a pH of about 4. In one embodiment, the disclosed and claimed etching formulations have a pH of about 3. In one embodiment, the disclosed and claimed etching formulations have a pH of about 2. In one embodiment, the disclosed and claimed etching formulations have a pH of about 1. In one embodiment, the disclosed and claimed etching formulations have a pH of about 0. In one embodiment, the disclosed and claimed etching formulations have a pH of about 0.5. In one embodiment, the disclosed and claimed etching formulations have a pH of about 0.3. In one embodiment, the disclosed and claimed etching formulations have a pH of about 0.1.

### Exemplary Embodiments

In one exemplary embodiment, the disclosed and claimed etching formulations include, consist essentially of or consist of:
(a) about 30 wt % to about 75 wt % of neat phosphoric acid;
(b) about 1.5 wt % to about 19.5 wt % of neat H₂O₂;
(c) about 0.001 wt % to about 3.0 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes polyethyleneimine. In a further aspect of this embodiment, the at least one neat cationic polymer corrosion inhibitor consists essentially of polyethyleneimine. In a further aspect of this embodiment, the at least one neat cationic polymer corrosion inhibitor consists of polyethyleneimine. In a further aspect of this embodiment, the at least one neat cationic polymer corrosion inhibitor includes diallyldimethylammonium chloride. In a further aspect of this embodiment, the at least one neat cationic polymer corrosion inhibitor consists essentially of diallyldimethylammonium chloride. In a further aspect of this embodiment, the at least one neat cationic polymer corrosion inhibitor consists of diallyldimethylammonium chloride. In a further aspect of this embodiment, the at least one neat cationic polymer corrosion inhibitor includes polydiallyldimethylammonium chloride. In a further aspect of this embodiment, the at least one neat cationic polymer corrosion inhibitor consists essentially of polydiallyldimethylammonium chloride. In a further aspect of this embodiment, the at least one neat cationic polymer corrosion inhibitor consists of polydiallyldimethylammonium chloride.

In one exemplary embodiment, the disclosed and claimed etching formulations include, consist essentially of or consist of:
(a) about 30 wt % to about 75 wt % of neat phosphoric acid;
(b) about 6 wt % to about 19.5 wt % of neat H₂O₂;
(c) about 0.001 wt % to about 3.0 wt % of at least one neat cationic polymer corrosion inhibitor; and
(d) a balance of solvent.
   In a further aspect of this embodiment, the solvent consists essentially of water. In a further aspect of this embodiment, the solvent consists of water.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.001 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.005 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.01 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.02 wt % of at least one cationic polymer corrosion inhibitor;
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.06 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 62 wt % of neat phosphoric acid;
(b) about 6 wt % of neat H₂O₂;
(c) about 0.015 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 27 wt % of neat phosphoric acid;
(b) about 19.5 wt % of neat H₂O₂;
(c) about 0.006 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 25.5 wt % of neat phosphoric acid;
(b) about 13.5 wt % wt % of neat H₂O₂;
(c) about 0.01% wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 46.3 wt % of neat phosphoric acid;
(b) about 13.5 wt % of neat H₂O₂;
(c) about 0.01 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes Lupasol® FG. In a further aspect of this embodiment, the at least one neat cationic polymer corrosion inhibitor consists essentially of Lupasol® FG. In a further aspect of this embodiment, the at least one neat cationic polymer corrosion inhibitor consists of Lupasol® FG.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.0175 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes diallyldimethylammonium chloride. In a further aspect of this embodiment, the at least one neat cationic polymer corrosion inhibitor consists essentially of diallyldimethylammonium chloride. In a further aspect of this embodiment, the at least one neat cationic polymer corrosion inhibitor consists of diallyldimethylammonium chloride.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.0525 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes diallyldimethylammonium chloride. In a further aspect of this embodiment, the at least one neat cationic polymer corrosion inhibitor consists essentially of diallyldimethylammonium chloride. In a further aspect of this embodiment, the at least one neat cationic polymer corrosion inhibitor consists of diallyldimethylammonium chloride.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.175 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes diallyldimethylammonium chloride. In a further aspect of this embodiment, the at least one neat cationic polymer corrosion inhibitor consists essentially of diallyldimethylammonium chloride. In a further aspect of this embodiment, the at least one neat cationic polymer corrosion inhibitor consists of diallyldimethylammonium chloride.

In one exemplary embodiment, the disclosed and claimed etching formulations include, consist essentially of or consist of:
(a) about 42.5 wt % of neat phosphoric acid;
(b) about 13.5 wt % of neat H₂O₂;
(c) about 0.525 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes diallyldimethylammonium chloride. In a further aspect of this embodiment, the at least one neat cationic polymer corrosion inhibitor consists essentially of diallyldimethylammonium chloride. In a further aspect of this embodiment, the at least one neat cationic polymer corrosion inhibitor consists of diallyldimethylammonium chloride.

In one exemplary embodiment, the disclosed and claimed etching formulations include, consist essentially of or consist of:
(a) about 25.5 wt % of neat phosphoric acid;
(b) about 13.5 wt % of neat H₂O₂;
(c) about 0.0525 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes diallyldimethylammonium chloride. In a further aspect of this embodiment, the at least one neat cationic polymer corrosion inhibitor consists essentially of diallyldimethylammonium chloride. In a further aspect of this embodiment, the at least one neat cationic polymer corrosion inhibitor consists of diallyldimethylammonium chloride.

In one exemplary embodiment, the disclosed and claimed etching formulations include, consist essentially of or consist of:
(a) about 46.6 wt % of neat phosphoric acid;
(b) about 13.5 wt % of neat H₂O₂;
(c) about 0.0525 wt % of at least one neat cationic polymer corrosion inhibitor; and
(d) a balance of solvent.
   In a further aspect of this embodiment, the solvent includes water. In a further aspect of this embodiment, the solvent consists essentially of water. In a further aspect of this embodiment, the solvent consists of water. In a further aspect of this embodiment, the at least one neat cationic polymer corrosion inhibitor includes diallyldimethylammonium chloride. In a further aspect of this embodiment, the at least one neat cationic polymer corrosion inhibitor consists essentially of diallyldimethylammonium chloride. In a further aspect of this embodiment, the at least one neat cationic polymer corrosion inhibitor consists of diallyldimethylammonium chloride.

It is to be understood that the disclosed and claimed subject matter includes, but is not limited to, the forgoing exemplary embodiments.

### Methods of Manufacture

The disclosed and claimed subject matter further includes method of manufacturing the disclosed and claimed etching formulations.

In one embodiment, the method for forming the etching composition includes combining:
(a) at least phosphorous containing acid or salt thereof;
(b) at least one oxidizing agent;
(c) at least cationic polymer corrosion inhibitor; and
(d) at least one solvent.

Thus, in one embodiment, the method for forming the etching composition includes the steps of:
(i) forming a part A composition by combining (a) at least phosphorous containing acid, (c) at least at least cationic polymer corrosion inhibitor, (d) at least one solvent;
(ii) combining the part A composition with (b) at least one oxidizing agent. In one aspect of this embodiment, the (d) at least one solvent includes water. In one aspect of this embodiment, the (d) at least one solvent consists essentially of water. In one aspect of this embodiment, the (d) at least one solvent consists of water.

### Methods of Use

The disclosed and claimed subject matter further includes a method of using the disclosed and claimed etching compositions to selectively remove a TiN layer while minimizing the etch rate of W layer and to a method for fabricating a semiconductor, which includes an etching process employing the disclosed and claimed etching compositions. The wafer device is exposed to the etching composition for a desired amount of time, at a desired temperature. Subsequently, the wafer device is removed from the etching composition, rinsed in de-ionized water, and dried by exposure to nitrogen gas.

In one embodiment, the method includes the steps of:
a. contacting the composite semiconductor device including TiN layer and W layer film with one or more of the etching compositions disclosed and claimed herein; and
b. rinsing the composite semiconductor device after the TiN layer is at least partially removed.
   In as further aspect of this embodiment, the contacting step is performed at a temperature of about 25° C. to about 90° C.

In a further embodiment, the method can include c. a drying step.

In the described methods, “at least partially removed” means removal of at least 90% of the material, preferably at least 95% removal. Most preferably, at least 99% removal using the compositions of the present development.

In some embodiments, the contacting step can be carried out by any suitable means such as, for example, immersion, spray, or via a single wafer process.

In some embodiments, the temperature of the composition during the contacting step is preferably from about 25° C. to about 90° C. In a further aspect, the temperature is about 30° C. to about 60° C. In a further aspect, the temperature is about 40° C. to about 60° C. In a further aspect, the temperature of the composition during the contacting step is about 50° C.

In some embodiments, the etch selectivity of TiN over W of the disclosed and claimed subject etch compositions is above about 1. In some embodiments, the etch selectivity of TiN over We of the disclosed and claimed subject etch compositions is above about 5. In some embodiments, the etch selectivity of TiN over W of the disclosed and claimed subject etch compositions is above about 10. In some embodiments, the etch selectivity of TiN over W of the disclosed and claimed subject etch compositions is above about 20. In some embodiments, the etch selectivity of TiN over W of the disclosed and claimed subject etch compositions is above about 50. In some embodiments, the etch selectivity of TiN over W of the disclosed and claimed subject etch compositions is above about 100.

In some embodiments, the W etch is less than about 5 Å/min. In a further aspect the W etch is less than about 3 Å/min. In a further aspect, the W etch is less than about 1 Å/min.

In some embodiments, the rinsing step is carried out by any suitable means, for example, rinsing the substrate with de-ionized water by immersion or spray techniques. In another aspect, the rinsing step is carried out employing a mixture of de-ionized water and a water-miscible organic solvent such as, for example, isopropyl alcohol.

In some embodiments, the drying step is carried out by any suitable means, for example, isopropyl alcohol (IPA) vapor drying, heat, or by centripetal force.

It is contemplated that the disclosed and claimed formulations are used in a “drain mode” process, in which the cleaning composition is used once, then is removed from the system by being directed to waste. Optionally, the cleaning compositions described herein may be utilized in a circulation mode system, where after use on a wafer or device, the composition is recycled for treatment of additional wafers or devices. In a circulation mode system, the components of the cleaning composition other than the solvent and oxidant are preferably provided in higher concentrations than is needed in a drain mode system.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

All ingredients used herein are commercially available.

All compositions which are the subject of the present examples were prepared by mixing the components in a 100 ml beaker with a 1″ Teflon-coated stir bar. Typically, the first material added to the beaker was deionized (DI) water. Other components were then added to dissolve in water to make the compositions.

Etching tests were run using 100 g of the etching compositions in a 150 mL beaker with a 1″ round Teflon stir bar set at 400 rpm. The etching compositions were heated to a temperature of 30-60° C. on a hot plate and then 2 cm×2 cm wafer coupons were immersed in the solutions for processing time between 2 minutes to 10 minutes. The wafer coupons were then rinsed for 3 minutes in a DI water bath and subsequently dried using nitrogen gas. The TiN rates were estimated from changes in the thickness before and after etching and was measured by spectroscopic ellipsometry (SCI Filmtek 2000 PAR-SE). The W rates were estimated from changes in the thickness before and after etching and was measured by CDE 4-probe Resmap. Typical starting layer thickness was 1000 Å for W and 3000 Å for TiN.

The following series of tables show the evaluation of several aspects of the compositions evaluated. In the following tables, neat concentrations of ingredients, where appropriate, are shown in parentheses. The water in the below tables is neat.

Table 1 shows the TiN and W etch rates at 50° C. in formulations with different Lupasol® FG concentrations and hydrogen peroxide concentrations. The pH value for these formulations was determined to be about 0.3. W and TiN blanket film coated coupon was soaked in these formulations at 50° C. for 2-10 minutes. The results clearly showed the addition of Lupasol® FG significantly decreased W etch rates while TiN etch rates slightly decreased. In the formulations with higher hydrogen peroxide concentration or lower phosphoric acid concentration significantly decrease TiN etch rates. In Table 1, Example 1 is a comparative example.

TABLE 1
Effect of Lupasol ® FG Concentration on W and TiN Etch Rates

| Component | CAS# | 1 | 2 | 3 | 4 | 5 | 6 | 7 |
|---|---|---|---|---|---|---|---|---|
| H₃PO₄ (85%) | 7664-38-2 | 50 | 50 | 50 | 50 | 50 | 72.73 | 31.82 |
| | | (42.5) | (42.5) | (42.5) | (42.5) | (42.5) | (61.8) | (27) |
| Lupasol ® FG | 9002-98-6 | — | 0.05 | 0.5 | 1 | 3 | 0.73 | 0.32 |
| (2% aq.) | | | (0.001) | (0.01) | (0.02) | (0.06) | (0.0146) | (0.0064) |
| H₂O | 7732-18-5 | 44 | 43.999 | 43.99 | 43.98 | 43.94 | 32.1854 | 53.4936 |
| H₂O₂ (30%) | 7722-84-1 | 45 | 45 | 45 | 45 | 45 | 20 | 65 |
| | | (13.5) | (13.5) | (13.5) | (13.5) | (13.5) | (6) | (19.5) |

| | | | | | | | |
|---|---|---|---|---|---|---|---|
| Total | 100 | 100 | 100 | 100 | 100 | 100 | 100 |
| W E/R (5 min) | 62.1 | <1 | <1 | <1 | <1 | <1 | 13.4 |
| TiN E/R(4 min) | 400.2 | 356.7 | 295.7 | 281.6 | 220.8 | >300 | <1 |

Table 2 shows the TiN and W etch rates at 50° C. in formulations with different phosphoric acid concentration. Clearly lower phosphoric concentration resulted in lower TiN etch rates while no obvious change in W etch rates.

TABLE 2
Effect of Phosphoric Acid Concentration on Etch Rates

| Component | CAS# | 8 | 3 | 9 |
|---|---|---|---|---|
| H₃PO₄ (85%) | 7664-38-2 | 30 | 50 | 54.5 |
| | | (25.5) | (42.5) | (46.325) |
| Lupasol ® FG (2% aq.) | 9002-98-6 | 0.5 | 0.5 | 0.5 |
| | | (0.01) | (0.01) | (0.01) |
| H₂O | 7732-18-5 | 60.99 | 43.99 | 40.165 |
| H₂O₂ (30%) | 7722-84-1 | 45 | 45 | 45 |
| | | (13.5) | (13.5) | (13.5) |

| | | | |
|---|---|---|---|
| Total | 100 | 100 | 100 |
| W E/R (5 min) | <1 | <1 | <1 |
| TiN E/R(4 min) | 82.3 | 295.7 | 310.0 |

Table 3 showed the TiN and W etch rates at 50° C. in formulations with different diallyldimethylammoniumchloride concentrations and phosphoric acid concentrations. The pH value for these formulations was determined to be around 0.3. W and TiN blanket film coated coupon was soaked in these formulations at 50° C. for 2-10 minutes. The results clearly showed the addition of diallyldimethylammonium chloride significantly decreased W etch rates while TiN etch rates slightly decreased. Lower phosphoric concentration resulted in lower TiN etch rates while no obvious change in W etch rates. In Table 3, Induquat ECR 35 L is an aqueous solution of diallyldimethylammonium chloride and Example 10 is a comparative example.

TABLE 3
Effect of Diallyldimethylammonium Chloride Concentration on Etch Rates

| Component | CAS# | 10 | 11 | 12 | 13 | 14 | 15 | 16 |
|---|---|---|---|---|---|---|---|---|
| H₃PO₄ | 7664-38-2 | 50 | 50 | 50 | 50 | 50 | 30 | 54.85 |
| (85%) | | (42.5) | (42.5) | (42.5) | (42.5) | (42.5) | 25.5 | (46.6) |
| Induquat | 26062-79-3 | — | 0.05 | 0.15 | 0.5 | 1.5 | 0.15 | 0.15 |
| ECR 35 L | | | (0.0175) | (0.0525) | (0.175) | (0.525) | (0.0525) | (0.0525) |
| (35% aq.) | | | | | | | | |
| H₂O | 7732-18-5 | 44 | 43.9825 | 43.9475 | 43.825 | 43.475 | 60.9475 | 39.8475 |
| H₂O₂ (30%) | 7722-84-1 | 45 | 45 | 45 | 45 | 45 | 45 | 45 |
| | | (13.5) | (13.5) | (13.5) | (13.5) | (13.5) | (13.5) | (13.5) |

| | | | | | | | |
|---|---|---|---|---|---|---|---|
| Total | | 100 | 100 | 100 | 100 | 100 | 100 |
| W E/R (5 min) | 62.1 | 3.0 | 1.2 | 1.9 | 1.1 | 3.1 | 1.6 |
| TiN E/R(4 min) | 400.2 | 344.2 | 328.9 | 347.8 | 329.6 | 195.7 | 360.3 |

The foregoing examples and description of the preferred embodiments should be taken as illustrating, rather than as limiting the present invention as defined by the claims. As will be readily appreciated, numerous variations and combinations of the features set forth above can be utilized without departing from the present invention as set forth in the claims. Such variations are not regarded as a departure from the spirit and scope of the invention, and all such variations are intended to be included within the scope of the following claims.

1. An etching formulation comprising:
(a) at least one phosphorous containing acid or salt thereof;
(b) at least one oxidizing agent;
(c) at least one cationic polymer corrosion inhibitor; and
(d) water.

2. The etching formulation of claim 1, wherein the at least one phosphorous containing acid or salt thereof comprises one or more of phosphoric acid, tetramethylammonium phosphate, tetrabutylammonium phosphate, tetraethylammonium phosphate, tetrapropylammoniumphosphate, etidronic acid, amino trimethylene phosphonic acid, tripolyphosphoric acid, tetrapolyphosphoric acid, pyrophosphoric acid, polymetaphosphoric acid, hypophosphorous acid, phosphorous acid, diphosphorous acid, triphosphorous acid, (aminomethyl)phosphonic acid, (aminoethyl)phosphonic acid, (aminopropyl)phosphonic acid, mono-n-dodecyl phosphate, tetramethylammonium phosphate, tetrabutylammonium phosphate, tetraethylammonium phosphate, tetrapropylammoniumphosphate and combinations thereof.

3. The etching formulation of claim 1, wherein the at least one phosphorous containing acid or salt thereof comprises phosphoric acid.

4. (canceled)

5. (canceled)

6. The etching formulation of claim 1, wherein the formulation comprises about 25 wt % to about 50 wt % of phosphoric acid.

7. The etching formulation of claim 1, wherein the at least one oxidizing agent comprises one or more of hydrogen peroxide, ammonium persulfate, peracetic acid, peroxybenzoic acid, oxone (2KHSO₅·KHSO₄·K₂SO₄), n-methylmorpholine oxide (NMMO or NMO), benzoyl peroxide, tetrabutylammonium peroxymonosulfate, ferric chloride, permanganate peroxoborate, periodic acid, iodic acid, vanadium (V) oxide, vanadium (IV, V) oxide, ammonium vanadate, perchlorate, persulfate, ammonium peroxydisulfate, per acetic acid, urea hydroperoxide, nitric acid (HNO₃), ammonium hypochlorite (NH₄CIO), ammonium tungstate ((NH₄)₁₀H₂(W₂O₇)), ammonium chlorite (NH₄CIO₂), ammonium chlorate (NH₄CIO₃), ammonium iodate (NH₄IO₃), ammonium perborate (NH₄BO₃), ammonium perchlorate (NH₄CIO₄), ammonium periodate (NH₄IO₃), ammonium persulfate ((NH₄)₂S₂O₈), tetramethylammonium chlorite ((N(CH₃)₄) CIO₂), tetramethylammionium chlorate ((N(CH₃)₄) CIO₃), tetramethylammonium iodate ((N(CH₃)₄) IO₃), tetramethylammonium perborate ((N(CH₃)₄) BO₃), tetramethylammonium perchlorate ((N(CH₃)₄) CIO₄), tetramethylammonium periodate ((N(CH₃)₄) IO₄), tetramethylammonium persulfate ((N(CH₃)₄)S₂O₈), ((CO(NH₂)₂)H₂O₂), peracetic acid (CH(CO)OOH) and combinations thereof.

8. The etching formulation of claim 1, wherein the at least one oxidizing agent comprises hydrogen peroxide.

9. (canceled)

10. The etching formulation of claim 1, wherein the formulation comprises about 6 wt % to about 20 wt % of neat hydrogen peroxide.

11. The etching formulation of claim 1, wherein the at least one cationic polymer corrosion inhibitor comprises on or more of polyalkyleneimine and its derivatives, poly(diallyldimethylammonium chloride), diallyldimethylammonium chloride and combinations thereof.

12. The etching formulation of claim 1, wherein the at least one cationic polymer corrosion inhibitor comprises polyethyleneimine.

13. The etching formulation of claim 1, wherein the formulation comprises about 0.001 wt % to about 5 wt % of the at least one cationic polymer corrosion inhibitor.

14-22. (canceled)

23. The etching formulation of claim 1, wherein the formulation comprises about 40 wt % to about 50 wt % of water.

24. (canceled)

25. The etching formulation of claim 1 comprising:
(a) about 30 wt % to about 75 wt % of neat phosphoric acid;
(b) about 1.5 wt % to about 19.5 wt % of neat H₂O₂;
(c) about 0.001 wt % to about 3.0 wt % of at least one neat cationic polymer corrosion inhibitor; and
(d) a balance of water.

26. (canceled)

27. The etching formulation of claim 1 comprising:
(a) about 30 wt % to about 75 wt % of neat phosphoric acid;
(b) about 6 wt % to about 19.5 wt % of neat H₂O₂;
(c) about 0.001 wt % to about 3.0 wt % of at least one neat cationic polymer corrosion inhibitor; and
(d) a balance of water.

28. The etching formulation of claim 1 comprising:
(a) about 42.5 wt % of neat phosphoric acid;
(b) about 13.5 wt % of neat H₂O₂;
(c) about 0.001 wt % of at least one neat cationic polymer corrosion inhibitor comprising polyethyleneimine; and
(d) a balance of water.

29. The etching formulation of claim 1 comprising:
(a) about 42.5 wt % of neat phosphoric acid;
(b) about 13.5 wt % of neat H₂O₂;
(c) about 0.001 wt % of at least one neat cationic polymer corrosion inhibitor; and
(d) a balance of water.

30. (canceled)

31. (canceled)

32. The etching formulation of claim 1 comprising:
(a) about 42.5 wt % of neat phosphoric acid;
(b) about 13.5 wt % of neat H₂O₂;
(c) about 0.01 wt % of at least one neat cationic polymer corrosion inhibitor comprising polyethyleneimine; and
(d) a balance of water.

33. The etching formulation of claim 1 comprising:
(a) about 42.5 wt % of neat phosphoric acid;
(b) about 13.5 wt % of neat H₂O₂;
(c) about 0.01 wt % of at least one neat cationic polymer corrosion inhibitor; and
(d) a balance of water.

34. (canceled)

35. (canceled)

36. The etching formulation of claim 1 comprising:
(a) about 42.5 wt % of neat phosphoric acid;
(b) about 13.5 wt % of neat H₂O₂;
(c) about 0.06 wt % of at least one neat cationic polymer corrosion inhibitor; and
(d) a balance of water.

37-47. (canceled)

48. The etching formulation of claim 1 comprising:
(a) about 42.5 wt % of neat phosphoric acid;
(b) about 13.5 wt % of neat H₂O₂;
(c) about 0.0525 wt % of at least one neat cationic polymer corrosion inhibitor; and
(d) a balance of water.

49. (canceled)

50. The etching formulation of claim 1 comprising:
(a) about 42.5 wt % of neat phosphoric acid;
(b) about 13.5 wt % of neat H₂O₂;
(c) about 0.175 wt % of at least one neat cationic polymer corrosion inhibitor; and
(d) a balance of water.

51. (canceled)

52. The etching formulation of claim 1 comprising:
(a) about 42.5 wt % of neat phosphoric acid;
(b) about 13.5 wt % of neat H₂O₂;
(c) about 0.525 wt % of at least one neat cationic polymer corrosion inhibitor; and
(d) a balance of water.

53-56. (canceled)

57. A method of forming the etching composition of claim 1 comprising the steps of:
(i) forming a part A composition by combining (a) the at least phosphorous containing acid, (c) the at least at least cationic polymer corrosion inhibitor, and (d) the water;
(ii) combining the part A composition with (b) the at least one oxidizing agent.

58-65. (canceled)
